(19) United States
(12) Patent Application Publication
(10) Pub. No.: US 2004/0200418 A1
(43) Pub. Date: Oct. 14, 2004

(54) Plasma spray systems and methods of uniformly coating rotary cylindrical targets

(76) Inventor: Klaus Hartig, Avcoa, WI (US)

Correspondence Address: INTELLECTUAL PROPERTY GROUP, FREDRIKSON & BYRON, P.A., 200 SOUTH SIXTH STREET, SUITE 4000, MINNEAPOLIS, MN, 55402, US

(21) Appl. No.: 10/750,988

(22) Filed: Jan. 2, 2004

Related U.S. Application Data
(60) Provisional application No. 60/437,956, filed on Jan. 3, 2003.

(51) Int. Cl. C23C 16/00

(52) U.S. Cl. 118/723 MP

(57) ABSTRACT

The present invention relates to plasma spraying systems and their methods of use in the manufacturing of rotary sputtering targets. More specifically, the invention relates to plasma spraying systems that coordinate and facilitate the rotation and the lateral or longitudinal movement of the sputtering target, thereby providing a uniform application of coating to the target. These plasma spraying systems may also produce a stable and secure coating layer by controlling the deposition of various particle sizes emitted by the plasma spraying system and/or removing dust from the target before a coating is applied. The present invention may also include a vacuum device with an adjustable exhaust duct that assists in the reduction or elimination of oxygen or other atmospheric gas backstreaming into the vacuum chamber.

### FIELD OF THE INVENTION

The present invention relates to plasma spraying systems and methods of using such systems in the manufacturing of rotary sputtering targets. More specifically, the invention relates to plasma spraying systems that coordinate the movement of a sputtering target, control the particle size emitted, and possess optimal vacuum characteristics to thereby provide a uniform and stable application of coating to the target.

### BACKGROUND OF THE INVENTION

The process of coating a cylindrical target by utilizing a plasma system is a common practice known in the art. In general, a plasma spray coating process involves moving a vertically or horizontally positioned rotating cylindrical target through an atomized stream of coating material produced by a spray gun. The spray gun is generally positioned perpendicularly to the cylindrical target. In operation, the target is rotated while the plasma spray gun sprays the target, thereby coating the entire surface of the cylindrical target. One alternative that may be performed when coating the entire cylindrical target is to move the atomized stream emitted from the spray gun back and forth over the rotating cylindrical target. Another alternative is to move the cylindrical target laterally or longitudinally through the spray gun's atomized stream while the target is rotating.

It is known in the art to have a plasma system in which a plasma gun, in combination with a power supply, provides a transfer arc in the form of a flame of ionized gas between the gun and a work piece, or target. The plasma gun is typically mounted within an environmentally controlled closed container or chamber together with the target, and may be coupled to a scanning mechanism to direct a plasma stream onto various portions of the target. The plasma system also typically includes a vacuum system which is operably coupled to the closed chamber for evacuation of gases, particles and other materials from the chamber. The plasma stream acts as a conductor for ionized inert gas which is introduced at high temperature and may flow through the closed container at supersonic speeds such as Mach 2 or Mach 3. In this manner, powdered metals, metal wires and similar materials introduced at the plasma gun are entrained into the plasma stream for deposition on the target.

Additionally, cylindrical targets are widely used in magnetron sputtering systems for depositing thin coatings and films on substrates. However, the manufacture of rotary sputtering targets with plasma spraying devices known in the art, may produce targets with coatings of target material that have less than optimal integrity. For example, existing plasma spray devices tend to provide a target that initially includes a series of peaks and valleys. The peaks and valleys are generated by movement of the cylindrical target through the plasma spray in a repetitive or similar systematic path. The deposition of coatings along similar periodic or systematic paths of the rotary target provides continuous application of coating over the same paths on a target. Continuous coating of the same paths on a target creates varying coating thickness over the surface of the overall target and thereby produces targets that do not initially have a uniform coating.

While plasma spray systems have been disclosed or suggested in the prior art, they have not addressed the reduction or prevention of the crests and valleys that are initially formed on a coated cylindrical target. For example, U.S. Pat. No. 5,114,736 to Griffiths et al., discloses traversing a spray gun on a path parallel to the longitudinal axis of a rotating cylindrical substrate while directing an atomized stream of material onto the substrate. However, Griffiths et al., does not disclose or suggest a plasma spray system that demonstrably reduces or prevents the creation of crests and valleys over the entire surface of the target.

Kida et al., U.S. Pat. No. 5,354,446 provides another example of a plasma spray system. Kida et al., describes a plasma spray system wherein a cylindrical target is formed by laterally reciprocating a plasma gun many times while rotating the target by a lathe. Additionally, U.S. Pat. No. 4,290,877 to Blickensderfer, discloses a sputtering operation wherein a target is simultaneously rotated and moved back and forth beneath at least one disk cathode or sputtering target. Neither Kida et al. nor Blickensderfer disclose or suggest reducing the creation of crests and valleys on the surface of the cylindrical target. Similarly, none of the previously mentioned patents disclose or suggest coordinating the relative lateral or longitudinal and rotational movement of the spray source and the substrate in a systematic manner to provide a more uniform coating on the substrate.

In addition, rotary targets coated by plasma spraying techniques (as well as by other thermal spraying techniques) and devices known in the art may not possess the optimum integrity. The lack of integrity in a rotary target becomes ultimately evident when the target is utilized in a magnetron sputtering process. A magnetron sputtering process is normally conducted in an evacuated chamber containing a small quantity of an ionizable gas, for example, Argon. A voltage applied to the cylindrical target, with respect to either the vacuum chamber enclosure or a separate anode, creates plasma that is localized along the sputtering zone of the target by stationary magnets positioned within the target. The cylindrical target, which includes the material to be sputtered, is bombarded by ions present within the plasma, causing particles of the target material to be dislodged from the target and subsequently deposited as a film on a nearby substrate. It is advantageous to the production of optimum coating integrity if ion bombardment of the target dislodges the target material on essentially an atom-by-atom basis. For example, optimal coating quality may not be achieved if larger particles or pieces of the target material break away from the cylindrical target and are deposited on the substrate during the magnetron sputtering process.

The reduced integrity of the target material, plasma sprayed upon a target backing tube, may be caused by the deposition of very small plasma-sprayed particles along with particles of the desired size (e.g., larger particles) on the backing tube surface. Very small particles, similar to dust particles, may not adhere to the surface of the backing tube as readily as larger particles. The reduction of coating integrity may be attributed to the partial or complete hardening of smaller particles before they reach the surface of the backing tube. Such partial or complete hardening may inhibit the desired adherence to the target surface and may thereby create weakened target material deposits that are susceptible to separation from the target surface.

Plasma spray systems also generally include a vacuum assembly for the removal of gas and other materials, such as small particles, from the vacuum chamber. However, various vacuum assemblies utilized in plasma spray systems may experience backstreaming of oxygen and other atmospheric gases into the vacuum chamber. The backstreaming of such gases, such as oxygen, into the vacuum chamber during a plasma sputtering process can create undesired reactions with the materials being deposited on the backing tube, thereby contaminating the target material coated on the tube. The elimination of these undesirable reactions would increase the purity, integrity and value of the coated cylindrical target.

### SUMMARY OF THE INVENTION

Generally, the plasma spray system of the present invention includes embodiments comprising a vacuum chamber within which a controlled environment may be established. The present invention further includes a target assembly positioned within the vacuum chamber, the target assembly having a target drive assembly adapted to move a cylindrical target at varying rates. Also, the plasma spray systems of the present invention include one or more plasma spray devices operably adjoined to one or more power supplies and a plasma gas assembly. Generally, the plasma spray devices are positioned within the vacuum chamber in an orientation to direct a plasma stream toward a deposition zone in a varying location on the cylindrical target. The present invention also includes a vacuum system operably adjoined to the vacuum chamber, and one or more coating feeders operably adjoined to one or more plasma spray devices for providing a coating material to the plasma stream for deposition on the cylindrical target.

In a preferred embodiment of the present invention, the target drive assembly may be preprogrammed to move the cylindrical target at varying rates. The drive assembly may include one or more drives that move the cylindrical target back and forth laterally or longitudinally, as well as rotationally. The present invention reduces the occurrence of crest and valley deposition of coating material on the cylindrical target by varying the rate of movement of the target, and/or by varying the points along the path where the target starts and stops its movement. By varying the rate of movement laterally, longitudinally and/or rotationally, the path of coating deposit on the target is not repeated numerous times and the coating material does not accumulate on a single designated repetitive or periodic path. Use of variable start and stop points for the movement of the cylindrical target can be used to further prevent the uneven accumulation of material.

Further embodiments of the present invention may also include a particle control assembly having one or more particle control conduits. In these embodiments, particle control conduits are oriented to direct a gas flow across the plasma stream between the plasma spray device and the cylindrical target to divert smaller plasma-sprayed particles and other small particles beyond the cylindrical target. The plasma spray devices may be operatively connected to a supply of anaerobic and/or reducing gases. The gas stream diversion eliminates the incorporation of small particles in the coating applied to the cylindrical target, thereby reducing the coating strength and quality.

Additional embodiments of the plasma spray system may include a preclean gas assembly. Generally, a preclean gas assembly, according to the present invention, has one or more preclean gas conduits operably coupled to one or more gas storage units. The preclean gas conduits are oriented to direct a gas flow or systematic blast of gas onto a surface location of the cylindrical target proximate to the deposition zone, before the proximate location enters the plasma stream focused upon the deposition zone. The gas flow or blast of gas assists in the removal of small particles and dust buildup on the deposition zone before the zone is coated.

Furthermore, embodiments of the plasma spray system may include a vacuum system having a vacuum duct, including a venturi tube section. The duct is normally operably adjoined to the vacuum chamber. The vacuum system of such embodiments additionally includes a blower system coupled to the vacuum duct for generating a vacuum flow, a chamber outlet having a reversibly-constricting chamber outlet end, and a gas detector positioned proximate to the chamber outlet for monitoring the backstreaming of atmospheric gases.

In one embodiment of the present invention, the chamber outlet may comprise a telescope channel operably coupled to the reversibly-constricting chamber outlet end. The reversibly-constricting chamber outlet end is operably adjoined to compression devices that are in turn coupled to rollers. The compression devices can be maneuvered to apply pressure to the chamber outlet end and thereby constrict the chamber outlet end as the telescope channel is extended into the venturi tube section.

Finally, embodiments of the plasma spray system may include a central control unit preprogrammed to transmit and control the function of one or more components of the plasma spray system. For example, the control unit may control the function of the components including, but not limited to, the plasma spray devices, the power sources, the target assemblies, the drive assemblies, the coating feeders, the vacuum system, the water supplies, the chamber outlet, the telescope channel, the tightening clamp, the particle control assemblies, the preclean gas assemblies, and the gas assemblies.

### BRIEF DESCRIPTION OF THE DRAWINGS

FIG. 1 is a combined block diagram and perspective view, in partial cross section, of an embodiment of a plasma system, in accordance with the present invention.

FIG. 2 is a sectional view of an embodiment of a plasma spray device that may be included in the plasma spray system of the present invention.

FIG. 3 is a combined block diagram and perspective view, in partial cross section, of an embodiment of a plasma system that includes a particle control assembly, in accordance with the present invention.

FIG. 4 is a combined block diagram and perspective view, in partial cross section, of an embodiment of a plasma system that includes a preclean gas assembly, in accordance with the present invention.

FIG. 5 is a combined block diagram and perspective view, in partial cross section, of an embodiment of a plasma system that includes a particle control assembly and a preclean gas assembly, in accordance with the present invention.

FIG. 6 is a sectional view of an embodiment of a vacuum system that may be included in the plasma spray system of the present invention.

### DETAILED DESCRIPTION OF THE INVENTION

The present invention generally relates to plasma spray systems that coordinate and facilitate the lateral or longitudinal movement and rotation of a sputtering target backing tube, thereby providing a uniform application of coating to the resulting target. Embodiments of the plasma spray systems also produce a stable and secure coating layer by, optionally, controlling the deposit of the various particle sizes emitted by the plasma spraying system and removing dust and other particles from the target before a coating is applied. Additional embodiments of the present invention further include a vacuum device that provides optimal vacuum characteristics. The vacuum device of these embodiments includes an adjustable exhaust duct that assists in the reduction or elimination of oxygen or other atmospheric gases backstreaming into the vacuum chamber. Illustrative embodiments of the present invention will be described herein below.

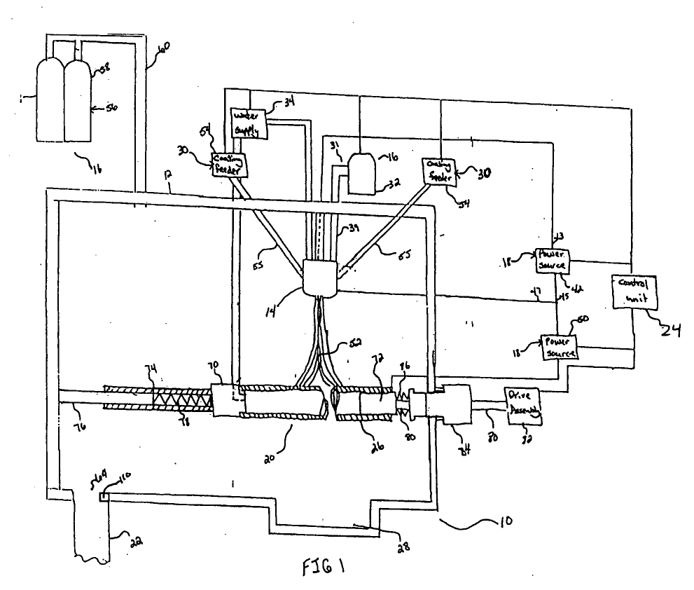

FIGS. 1 and 3-5 depict embodiments of a plasma spray system 10 wherein the system 10 comprises, a vacuum chamber 12, one or more plasma spray devices 14, one or more gas assemblies 16, one or more power sources 18, one or more target assemblies 20, a vacuum system 22 and, optionally, a central control unit 24. The vacuum chamber 12 includes a sealed vacuum-maintaining and pressure-resistant isolative enclosure. The chamber 12 may be of any shape or size, but is preferably of sufficient size and shape to accommodate one or more plasma spray devices 14 and the back and forth lateral and rotational movement of a cylindrical rotary target 26. It is noted that embodiments of the present invention may be configured to accommodate back and forth longitudinal movement of a cylindrical target 26 and lateral emission of a plasma spray onto the target 26. This may be accomplished by simply rotating the plasma spray system 10 by 90 degrees and further adjusting the location of the vacuum system 22 to provide for optimum evacuation of the chamber and removal of small particles and other vented material. The vacuum chamber 12 may optionally include a dust collection bin 28 for accumulation of small coating particles or other dust materials. The dust collection bin 28 may be of any shape including, but not limited to, a squared box or conical shape. The bottom of the dust collection bin 28 may include a trap door or clean-out (not shown) for easy access to the chamber and removal of excess sputtering material. Generally, the vacuum chamber walls, doors, and other components are comprised of a metallic material, such as stainless steal. However, any suitable material may be utilized in the manufacture of the vacuum chamber.

FIGS. 1 and 3-5 illustrate that the plasma spray system 10 includes one or more plasma spray devices 14 that may be operably connected to one or more power supplies 18, one or more coating feeder apparatuses 30, and a plasma gas assembly 31 and are normally positioned within the vacuum chamber 12. Generally, the plasma gas assembly 31 includes one or more gas sources 32, such as one or more containers of Argon, and one or more plasma gas transfer lines 39 extending from the gas sources 32 to the plasma spray device 14. The plasma spray device 14 may also be operably connected to a water supply 34 to cool the plasma spray device 14 and the cylindrical target 26 during operation.

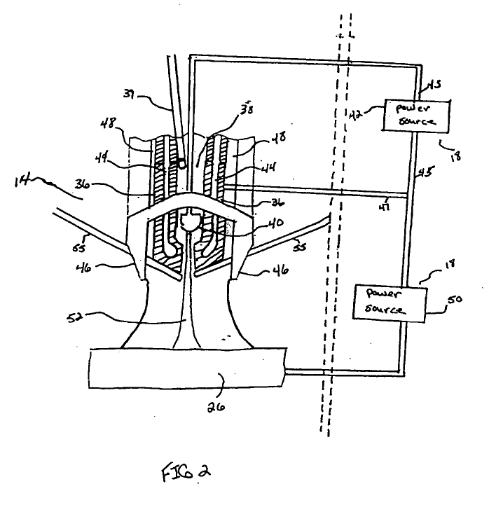

FIG. 2 depicts a sectional view of one embodiment of a plasma spray device 14. In this embodiment the plasma spray device 14 includes a nozzle 36 having a conical cavity 38 that tapers downward. The nozzle 36 may be manufactured of any suitable material, such as copper. The conical cavity 38 is adapted to receive one or more plasma gas transfer lines 39 and an electrode 40 that is operably connected to a power source 18, more specifically, a plasma power source 42. The plasma transfer lines 39 are operably connected to the plasma gas source 32, as depicted in FIG. 1, and function as the conduit for the transfer of gas utilized to create the plasma in the system 10. The electrode 40 housed within the nozzle 36 may be made of any suitable material, e.g., tungsten. Further, the nozzle 36 may optionally include water conduits 44 for receiving water from the water supply 34 (of FIG. 1), which cools the nozzle 36 during operation.

The nozzle 36 may optionally be enclosed within a housing 46. A gas passage 48 may be positioned between the housing 46 and the nozzle 36 to allow for an additional gas to flow through the plasma spray device 14. The gas provided to the gas passage 48 may be supplied through a gas conduit similar to plasma gas transfer line 39, by one or more gas sources, similar to the plasma gas source 32 (of FIG. 1). The additional gas may be utilized as a shielding gas or may include a reactive gas depending upon the coating desired.

The plasma spray device 14 is operably connected to one or more power sources 18. FIGS. 1-5 depict the plasma spray device 14 and the cylindrical target 26 operably connected to multiple power sources 18: a plasma power source 42 and a transfer arc power source 50. The plasma power source 42 has a negative terminal 43 coupled to the electrode 40 and a positive terminal 45 coupled to the target 26. The plasma power source 42 renders the target 26 positive relative to the plasma spray device 14 so that an electron flow is in the direction from the plasma spray device 14 to the cylindrical target 26 thereby producing a plasma stream 52. Furthermore, a second positive terminal 47 of the plasma power source 42 is operably coupled to the nozzle 36 to produce a pilot arc between the nozzle 36 and the negatively charged electrode 40. The pilot arc generally produces the initial ionization of the plasma gas prior to the generation of an arc between the plasma spray device 14 and the target 26.

The plasma spray device 14 and the cylindrical target 26 may be optionally coupled to a transfer arc power source 50. When activated, the transfer arc power source supply 50 causes electrons to flow in a reverse transfer arc out of the cylindrical target's 26 surface and flow countercurrent through the plasma stream 52. The action of the reverse transfer arc discharges at the surface of the cylindrical target 26 and thereby vaporizes and eliminates any surface contaminants.

A further embodiment of the plasma spray device 14 includes operably coupling the device to one or more coating feeders 30, as depicted in FIGS. 1-5. The coating feeder apparatuses 30 may be of any suitable feeder type, for example, powder feeders and wire feeders. Generally, the coating feeder apparatuses 30 include a coating hopper 54 and a transmission device 55. The coating hopper 54 may be of any size and shape that is appropriate for holding and efficiently transferring coating powder or coating wire to the plasma spray device 14. The coating hopper 54 is operably adjoined to the coating transmission device 55. The coating transmission device 55 transmits powders to the plasma stream 52 and may be any suitable conduit and/or other device, such as metal or polymeric tubing. Alternately, the coating device may be a guiding device for the maneuvering of wire to the plasma stream 52. As suggested, the coating powder or coating wire is directed into the plasma spray stream 52 and sprayed onto a deposition zone located on the backing tube of target 26. The deposition zone is generally the location wherein the plasma sprayed material is intended to contact the backing tube of the target 26.

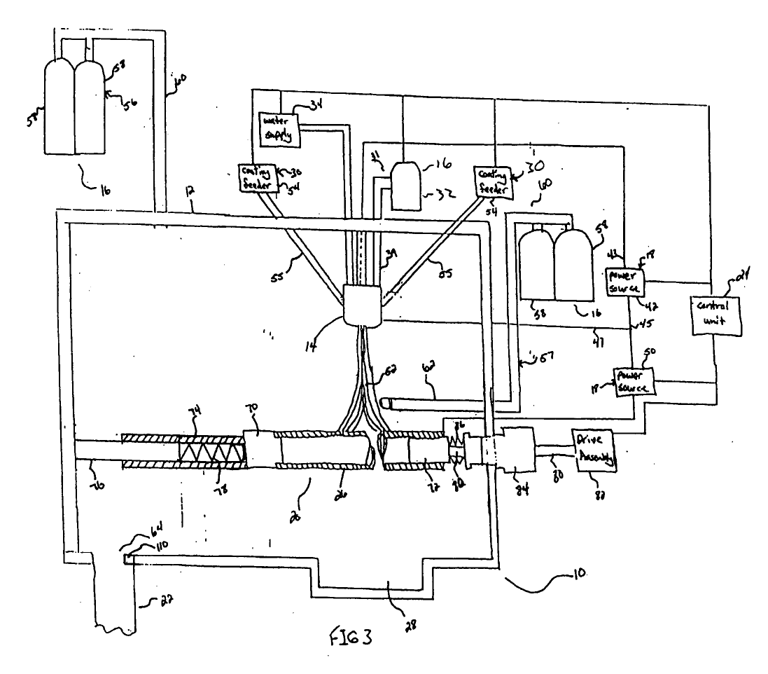

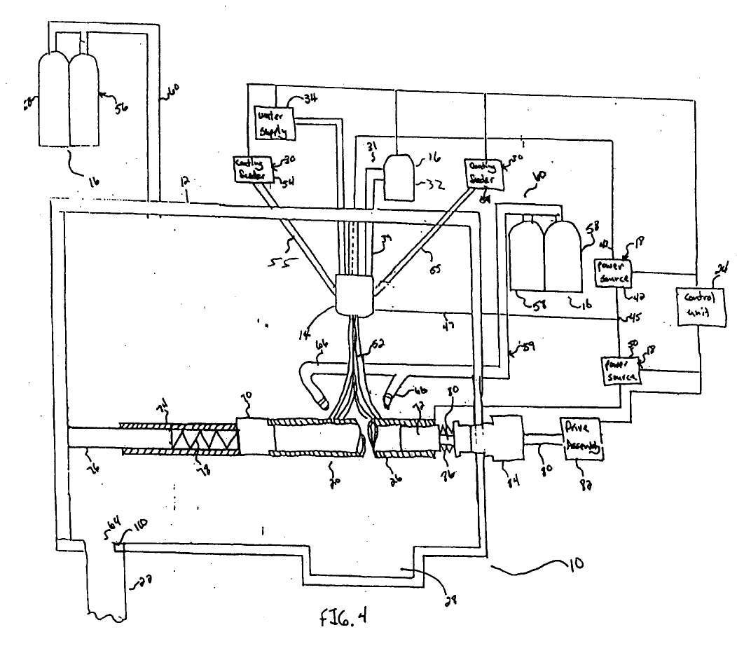

The plasma spray system 10 may further include one or more gas assemblies 16. As seen in FIGS. 1 and 3-5, various gas assemblies 16 including a plasma gas assembly 31, a chamber gas assembly 56, a particle control assembly 57 (FIGS. 3 & 5) and a preclean gas assembly 59 (FIGS. 4 & 5) may be included. The plasma gas assembly 31 was described in previous paragraphs of the Detailed Description of the Invention. The chamber gas assembly 56 (of FIG. 1) includes one or more gas storage units 58 and one or more gas conduits 60. The gas storage units 58 retain gases, such as argon, helium, hydrogen, nitrogen, oxygen or any combination thereof, that may be utilized in a plasma spray process. The gas conduits 60 are operably connected to the various gas storage units 58 and provide a line for movement of the gas from the storage units 58 to the vacuum chamber 12 or to the gas passage 48 within the plasma spray device 14 as previously described with reference to FIG. 2. The gas conduits 60 may be any type of device or apparatus suitable for carrying gas, such as a metallic or polymeric tubing.

FIG. 3 depicts another embodiment of a plasma spray system 10 that includes a particle control assembly 57. The particle control assembly 57 includes one or more gas storage units 58, normally positioned outside the vacuum chamber and operably coupled to one or more particle control conduits 62. The particle control conduits 62 may be any type of device or apparatus suitable for carrying gas, such as a metallic or polymeric tubing. The particle control conduit(s) 62 extend into the vacuum chamber 12 and are positioned to emit a controlled flow of gas through the plasma stream 52 and, optionally, toward an exhaust outlet 64. The flow of gas assists in the diversion of dust and very small coating particles, which would reduce the integrity of the coating being deposited, away from the cylindrical target surface (or at least away from the deposition zone). The speed of the gas flow may be fixed or may be predestinated or controlled by an automated control system at a rate for optimum removal of undesired particles, generally smaller than the desired particle sizes, but not at a rate that would remove the desired coating particle sizes. In one embodiment, at least one particle control conduit is adapted to emit a stream of gas generally crosswise through the plasma stream 52.

FIG. 4 illustrates a further embodiment of a plasma spray system 10 that includes a preclean gas assembly 59. The preclean gas assembly 59 includes one or more gas storage units 58, normally positioned outside the vacuum chamber and operably coupled to one or more preclean gas conduits 66. The preclean gas conduits 66 may be any type of device or apparatus suitable for carrying gas, such as a metallic or polymeric tubing. The preclean gas conduit(s) 66 extend into the vacuum chamber 12 and are positioned to emit a systematic blast or flow of gas onto the surface location of the cylindrical target 26 that is about to enter the plasma stream. The systematic blast or flow of gas is optimized to remove the dust and very small coating particles that may be considered detrimental to coating integrity. This activity removes any materials that would reduce the integrity of the coating being deposited, and/or contaminate the coated cylindrical target.

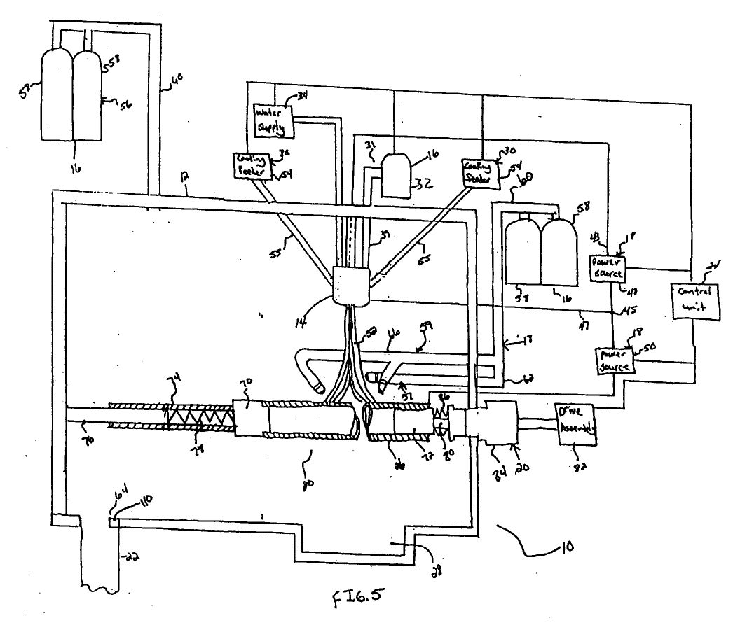

As depicted in FIG. 5, an embodiment of the plasma spray system 10 of the current invention may include both a particle control assembly 57 and a preclean gas assembly 59. The particle control assembly 57 and preclean gas assembly 59 may utilize the same or different storage units 58 and/or gas transfer conduits 60. The plasma spray system depicted in FIG. 5 simultaneously precleans the surface of the cylindrical target 26 before coating is deposited and removes dust and small particles from the plasma stream 52 during application of a coating.

Embodiments of the plasma spray system of the present invention further include one or more target assemblies 20. FIGS. 1 and 3-5 illustrate a target assembly that includes a cylindrical target 26 extending through the vacuum chamber 12 and operably supported at its ends by first and second plug support mounts 70 and 72 respectively. The first mount 70 is spring-loaded towards the second mount 72 by an assembly formed by a cylindrical sleeve 74 slidably mounted on a pin 76 and containing a compression spring 78. The assembly permits the first mount 70 to rotate the cylindrical target 26 about a central axis of the cylindrical core. The second mount 72 is positioned at one end of a shaft 80, the shaft extending to a drive assembly 82 by passing through a rotary sealing plug 84. The sealing plug 84 fits snugly within an opening in the vacuum chamber 12 and functions to seal the chamber 12. A second compression spring 86 may optionally be positioned around the shaft 80 within the interior of the vacuum chamber 12.

The target drive assembly 82 included in embodiments of the present invention may include one or more drives or motors of identical or varying types. For example, the drive assembly 82 may include a single drive or motor that provides rotary and either back and forth lateral or longitudinal movement of the cylindrical target 26. Alternatively, the target drive assembly 82 may be a combination of two or more drives or motors, wherein each drive or motor provides a single but different function from the additional drives or motors, or a redundant function. Drive or motor types include, but are not limited to, alternating current motors, hydraulic systems, pneumatic systems or any other type or device that would produce rotation and/or lateral or longitudinal movement of the cylindrical target 26.

In one embodiment of the present invention, the drive assembly 82 is preprogrammed to vary the rotational and/or lateral or longitudinal speed, for example, according to a pseudo-random pattern, or according to a systematic method. The drive assembly 82, in an additional embodiment, may be preprogrammed to start and/or stop the movement of cylindrical target 26 at random locations along its movement path. This change of rotational and/or lateral speed, as well as the inclusion of random start and/or stop points, inhibits or prevents the plasma stream from coating the same path on the cylindrical target 26. A more uniform coating is thus applied to the cylindrical target 26 and the initial creation of crests and valleys is greatly diminished. Alternatively, a central control unit 24 may be programmed to systematically (or pseudo-randomly) alter the pace or rate of the drive assembly and thereby avoid the initial production of crests and valleys on the cylindrical target 26.

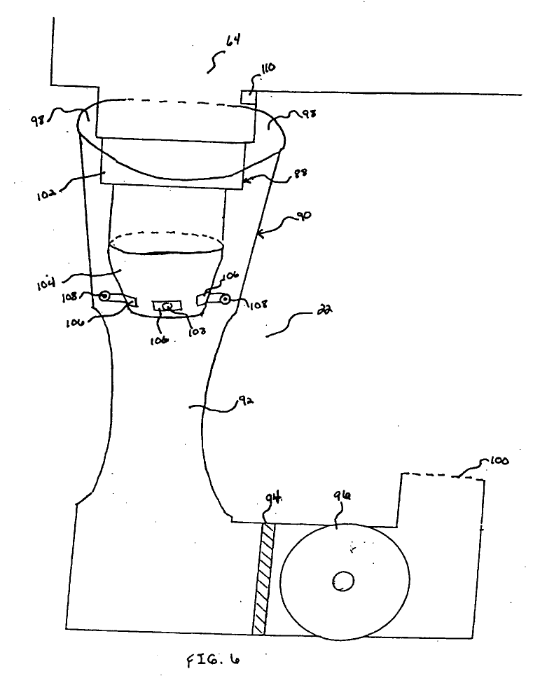

As depicted in FIGS. 1 and 3-5, the plasma spray system 10 of the present invention preferably includes a vacuum system 22. FIG. 6 further depicts one embodiment of a vacuum system 22 which may be utilized in the present invention. The vacuum system 22 comprises a chamber outlet 88 that feeds into a vacuum duct 90. The vacuum duct 90 includes a venturi tube section 92 that is generally utilized to create a pressure differential. The vacuum duct preferably houses a filter 94 for capturing dust and other particles vented from the vacuum chamber 12.

The vacuum duct 90 preferably includes a blower system 96 that produces a vacuum The continuing movement of atmospheric air through the vacuum duct 90 produces the vacuum, which assists in evacuating the undesired contents of the vacuum chamber 12. The vacuum pulls unwanted gases and materials out of the chamber by drawing atmospheric gases through a duct opening 98, passing by the opening of chamber outlet 88 and continuing through the vacuum duct until exiting back into the atmosphere at the duct vent 100.

A vacuum system 22 that passes atmospheric gas by a vacuum chamber opening may experience a slight backstreaming of atmospheric gases into the vacuum chamber that results in contamination. This unwanted contamination may be remedied by adding additional precautionary devices to the vacuum system 22. FIG. 6 depicts an embodiment of a vacuum system 22 including examples of such precautionary devices wherein the chamber outlet includes a telescope channel 102 operably coupled to a reversibly-constricting chamber outlet end 104. In this embodiment, the channel end 104 of the telescope channel 102 includes compression devices 106 that are operably connected to rollers 108. The compression device 106 may be a strip of rigid material, such as a metal clip, that form fits to the outside surface of the telescope chamber outlet end 104. Of course, any other suitable configuration of compression device may be used.

The compression devices 106 may be incorporated or molded into the chamber outlet end 104. Upon the detection of an unacceptable amount of atmospheric gases by a gas detector 110, e.g. an oxygen detector, the telescope channel 102 may be constricted by extending the telescope channel 102 into the venturi tube section 92. The rollers 108 move along the wall of the venturi tube section 92 as the telescope channel 102 is extended, thereby placing pressure on the compression devices 106 and constricting the chamber outlet end 104 of the telescope channel 102. The compression devices 106 and rollers 108 can be spaced regularly around the chamber outlet end 104 of the telescope channel 102. The regular spacing of the compression devices 106 and rollers 108 allows for openings between the chamber outlet end 104 and the walls of the venturi tube section 92. These openings provide for the constant flow of atmospheric air through the vacuum duct 90, thereby creating a continuous movement of gases through the vacuum system 22. The chamber outlet end 104 of the telescope channel 102 may be made of any flexible polymeric, rubber, or other suitable material that returns to the original form once compression ceases.

Alternatively, the chamber outlet end 104 may be comprised of a flexible material that constricts when impinged upon the inner surface of the venturi tube section 92 thereby reducing the size of the opening that may allow backstreaming of gases. Such a configuration may be utilized to eliminate the compression devices 106 and rollers 108.

Other means for constricting the chamber outlet end 104 may also be applied to the present invention to eliminate the need for a telescoping device. For example, a tightening clamp or belt (not depicted) wrapped around the chamber outlet end 104 or incorporated/molded into the chamber outlet end 104 may alternatively be applied to constrict the chamber outlet end 104 and thereby reduce the backstreaming of unwanted gases.

As depicted in FIGS. 1 and 3-5, the present invention may also include a central control unit 24. The central control unit 24 may comprise any computer system that may be programmed to transmit and control the functions of the plasma spray system 10. The central control unit 24 may be preprogrammed to transmit and control the function of one or more of the components of the plasma spray system 10. The drive assembly 82 may be controlled by a central control unit 24 to systematically alter the pace or rate of the drives or motors, thereby diminishing or avoiding the initial production of crests and valleys on the cylindrical target 26. Additionally, the central control unit 24 may be preprogrammed to receive readings from the optional gas detector 110, depicted in FIGS. 1 and 3-5, and sense whether the optimum level, if any, of atmospheric gases backstreaming into the vacuum chamber 12 is being exceeded. If the optimum level is exceeded, the central control unit may control the constriction of the telescope channel end 104 to reduce backstreaming. Additionally, the central control unit 24 may be preprogrammed to transmit and control the coating feeder apparatuses 30, the water supplies 34, the plasma spray devices 14, the power sources 18, the gas storage units 58 of plasma gas assembly 31, chamber gas assembly 56, particle control assembly 57, and preclean gas assembly 59 and for all other components in the system that provide a function to the plasma spray process.

In operation, a cylindrical target backing tube of a cylindrical target 26 is mounted to the target assembly 20 by inserting the first and second plug support mounts 70, 72 into the ends of the cylindrical target 26. Once properly mounted, the cylindrical target 26 may be rotated, and may also be moved in either a lateral or longitudinal manner, beneath one or more activated plasma spray devices 14, by one or more drive assemblies 82. During the activation of one or more plasma spray devices 14, one or more coating materials are fed by coating feeders 30 to the plasma spray devices 14, and plasma is sprayed onto the surface of the cylindrical target 26. During the plasma spraying process the rate of the rotational, lateral and/or longitudinal movement of the cylindrical target can be altered to reduce or prevent the continued or repetitive sputtering of the same path. Altering the rate of movement assists in eliminating the initial formation of crests and valleys of target material on the backing tube. In another alternative embodiment, the drive assembly 82, in an additional embodiment, may be preprogrammed to start and/or stop the movement of cylindrical target 26 at random locations along its movement path, which also serves to further eliminate the formation of crests and valleys in the target material.

As described above, the plasma spray devices of the present invention may include a particle control assembly 57 to aid in reducing contamination of the surface by unwanted particles. During the plasma spraying process, the particle control assembly 57 directs a flow of gas, using one or more particle control conduits 62, through (e.g., crosswise) the plasma stream 52. The flow of gas laterally diverts smaller particles beyond the surface of the cylindrical target 26 (or at least beyond the target surface region upon which the plasma stream impinges) to prevent or diminish their undesirable attachment to the target 26. While the particle control conduits 62 and preclean gas conduits 66 are depicted as running laterally along the longitudinal axis of the target assembly 20, they may alternately be disposed perpendicularly to this axis so as to not blow undesirable particles or contaminants to another location on the target itself. The small particles are generally diverted past the target and are drawn to an exhaust outlet 64 by a vacuum system 22 for removal from the vacuum chamber 12. In such embodiments the flow of gas may comprise any gas or combination of gases including but not limited to an anaerobic gas or reducing gas such as argon, helium, hydrogen, nitrogen, or methane.

Additionally, to remove undesired particles, the plasma spray devices may include a preclean gas assembly 59. During the plasma spraying process, a surface area of cylindrical target 26 that is positioned immediately in front of the surface area that is about to move through the plasma stream 52 is cleaned or blasted with an emission of gas. The emission of gas removes the undesirable dust or small particles from the surface of the cylindrical target 26. This precleaning process removes any materials which would reduce the integrity of the coating of target material being deposited and/or contaminate the coated cylindrical target.

The vacuum assembly 22, as described in a number of the previously mentioned embodiments, assists in the reduction and prevention of backstreaming of gases into the vacuum chamber 12. In operation, the gas detector 110 senses the level of atmospheric gas flowing into the vacuum chamber 12. Once the gas detector 110 senses that a predetermined level of backstream gas is entering the vacuum chamber 12, the chamber outlet end 104 is constricted, for example by control unit 24, to inhibit the backstreaming of gas into the vacuum chamber 12. In one embodiment of the present invention, the constriction of the chamber outlet end 104 is accomplished by extending the telescope channel 102 down the vacuum duct 90 and into the venturi tube section 92. Rollers 108 may then be pushed against the walls of the venturi tube section 92 to apply pressure to operably connected compression devices 106, thereby constricting the chamber outlet end 104. The chamber outlet end 104 may be returned to its original position by retracting the telescope channel 102. In another embodiment, the outlet chamber end 104 is constricted by tightening a clamp, gather, belt, trap, loop, band, or constrictor that surrounds the circumference of the outlet chamber end 104.

The present invention has been described herein primarily in the context of plasma spraying. As would be obvious to those skilled in the present art, however, this invention provides methods and apparatuses that have utility in a wide range of spraying applications. Accordingly, the term plasma spraying is used herein to describe any spraying method that can be used to spray a coating of material on an object. For example, it is to be understood that use herein of the term plasma spraying includes all of the different forms of spraying (e.g., thermal spraying, water plasma spraying, etc.) that can be used to apply a coating of target material upon the backing tube of a sputtering target (e.g., a rotary or cylindrical target) or upon any other article that may be coated by spraying methods. Those skilled in this art would be able to immediately apply the present methods and apparatuses to many other spraying methods, all of which would fall within the scope of this invention.

While the invention has been described in conjunction with specific embodiments thereof, it is evident that many alternatives, modifications, and variations will be apparent to those skilled in the art in light of the foregoing description. Accordingly, it is intended to embrace all such alternatives, modifications, and variations, which fall within the spirit and broad scope of the invention.

What is claimed is:

1. A plasma spray system, comprising:
a vacuum chamber;
one or more target assemblies positioned within the vacuum chamber, the target assemblies including one or more target drive assemblies adapted to move one or more cylindrical targets at varying rates;
one or more power supplies;
one or more plasma gas assemblies;
one or more plasma spray devices operably adjoined to the one or more power supplies and the one or more plasma gas assemblies, wherein the plasma spray devices are oriented to direct one or mores plasma streams toward one or more deposition zones on the cylindrical targets;
one or more coating feeder apparatuses operably adjoined to one or more plasma spray devices for providing a coating material to the plasma streams for deposition on the cylindrical targets; and
a vacuum system operably adjoined to the vacuum chamber.

2. The plasma spray system of claim 1 further comprising one or more particle control assemblies including one or more particle control conduits oriented to direct gas flows across the plasma streams between the plasma spray devices and the cylindrical targets to divert smaller plasma-sprayed particles and other small particles beyond the cylindrical targets.

3. The plasma spray system of claim 1 wherein the target drive assemblies are adapted to stop and start the motion of one or more cylindrical targets at varying points.

4. The plasma spray system of claim 2 wherein the one or more plasma spray devices are operatively connected to a supply of anaerobic gas.

5. The plasma spray system of claim 2 wherein the one or more plasma spray devices are operatively connected to a supply of reducing gas.

6. The plasma-spray system of claim 1 wherein the one or more target drive assemblies move the one or more cylindrical targets laterally with respect to the plasma spray device at a varying rate.

7. The plasma spray system of claim 1 wherein the one or more target drive assemblies rotate the one or more cylindrical targets about central axes of their cylindrical cores at a varying rate.

8. The plasma spray system of claim 5 wherein the one or more target drive assemblies rotate the one or more cylindrical target about central axes of their cylindrical cores at a varying rate.

9. The plasma spray system of claim 1 further comprising one or more preclean gas assemblies including one or more preclean gas conduits operably coupled to one or more gas storage units and oriented to direct gas flows or systematic blasts onto the deposition zones of the cylindrical targets before the deposition zones enter the plasma stream.

10. The plasma spray system of claim 2 further comprising a preclean gas assembly including one or more preclean gas conduits operably coupled to one or more gas storage units and oriented to direct a gas flow or systematic blast onto the deposition zones of the cylindrical targets before the deposition zones enter the plasma streams.

11. The plasma spray system of claim 1 wherein the vacuum system comprises a vacuum duct operably adjoined to the vacuum chamber, including:
a blower system coupled to the vacuum duct for generating a vacuum flow;
a chamber outlet having a reversibly constricting chamber outlet end;
a venturi tube section positioned between the vacuum chamber and the blower system; and
a gas detector positioned proximate to the chamber outlet for monitoring the backstreaming of atmospheric gases.

12. The plasma spray system of claim 11 wherein the chamber outlet includes a telescope channel operably coupled to the reversibly constricting chamber outlet end.

13. The plasma spray system of claim 12 wherein the reversibly constricting chamber outlet end includes compression devices operably coupled to rollers that apply pressure to the chamber outlet end thereby constricting the chamber outlet end as the telescope channel is extended into the venturi tube section.

14. The plasma spray system of claim 11 wherein the reversibly constricting chamber outlet includes a tightening clamp extending around the chamber outlet end.

15. The plasma spray system of claim 1 further comprising a central control unit preprogrammed to transmit and control the function of one or more components of the plasma spray system.

16. The plasma spray system of claim 15 wherein the one or more components of the plasma spray system are selected from the group consisting of plasma spray devices, power sources, target assemblies, drive assemblies, coating feeder apparatuses, the vacuum system, water supplies, chamber outlet, telescope channel, tightening clamp, particle control assemblies, preclean gas assemblies and gas assemblies.

17. A plasma spray system, comprising:
a vacuum chamber;
one or more target assemblies including one or more target drive assemblies configured to move one or more cylindrical targets rotationally, laterally, longitudinally or any combination thereof;
one or more power supplies;
one or more plasma gas assemblies;
one or more plasma spray devices operably adjoined to the one or more power supplies and the one or more plasma gas assemblies, wherein the plasma spray devices are oriented to direct a plasma stream toward a deposition zone on the cylindrical target;
one or more particle control assemblies including one or more particle control conduits oriented to direct gas flows across the plasma streams between the plasma spray devices and the cylindrical targets to divert smaller plasma-sprayed particles and other small particles beyond the cylindrical targets;
a vacuum system operably adjoined to the vacuum chamber; and
one or more coating feeder apparatuses operably adjoined to one or more plasma spray devices for providing a coating material to the plasma streams for deposition on the cylindrical targets.

18. The plasma spray system of claim 17 wherein the target drive assemblies are adapted to stop and start the motion of one or more cylindrical targets at varying points.

19. The plasma spray system of claim 17 further comprising one or more preclean gas assemblies including one or more preclean gas conduits operably coupled to one or more gas storage units and oriented to direct gas flows or systematic blasts onto the deposition zones of the cylindrical targets before the deposition zones enter the plasma stream.

20. The plasma spray system of claim 17 wherein the vacuum system comprises a vacuum duct operably adjoined to the vacuum chamber, including:
a blower system coupled to the vacuum duct for generating a vacuum flow;
a chamber outlet having a reversibly constricting chamber outlet end;
a venturi tube section positioned between the vacuum chamber and the blower system; and
a gas detector positioned proximate to the chamber outlet for monitoring the backstreaming of atmospheric gases.

21. The plasma spray system of claim 20 wherein the chamber outlet includes a telescope channel operably coupled to the reversibly constricting chamber outlet end.

22. The plasma spray system of claim 21 wherein the reversibly constricting chamber outlet end includes compression devices operably coupled to rollers that apply pressure to the chamber outlet end thereby constricting the chamber outlet end as the telescope channel is extended into the venturi tube section.

23. The plasma spray system of claim 17 wherein the reversibly constricting chamber outlet includes a tightening clamp extending around the chamber outlet end.

24. The plasma spray system of claim 17 further comprising a central control unit preprogrammed to transmit and control the function of one or more components of the plasma spray system.

25. The plasma spray system of claim 24 wherein the one or more components of the plasma spray system are selected from the group consisting of plasma spray devices, power sources, target assemblies, drive assemblies, coating feeder apparatuses, the vacuum system, water supplies, chamber outlet, telescope channel, tightening clamp, particle control assemblies, preclean gas assemblies and gas assemblies.

26. A plasma spray system, comprising:
a vacuum chamber;
one or more target assemblies positioned within the vacuum chamber, the target assemblies having one or more target drive assemblies configured to move one or more cylindrical targets rotationally, laterally, longitudinally or any combination thereof;
one or more power supplies;
one or more plasma gas assemblies;
one or more plasma spray devices operably adjoined to the one or more power supplies and the one or more plasma gas assemblies, wherein the plasma spray devices are oriented to direct one or more plasma streams toward one or more deposition zones on the cylindrical targets;
one or more coating feeder apparatuses operably adjoined to one or more plasma spray devices for providing a coating material to the plasma streams for deposition on the cylindrical targets;
one or more preclean gas assemblies including one or more preclean gas conduits operably coupled to one or more gas storage units and oriented to direct gas flows or systematic blasts onto the deposition zones of the cylindrical targets before the deposition zones enter the plasma stream; and
a vacuum system operably adjoined to the vacuum chamber.

27. The plasma spray system of claim 26 wherein the target drive assemblies are adapted to stop and start the motion of one or more cylindrical targets at varying points.

28. The plasma spray system of claim 26 further comprising one or more particle control assemblies including one or more particle control conduits oriented to direct gas flows across the plasma streams between the plasma spray devices and the cylindrical targets to divert smaller plasma-sprayed particles and other small particles beyond the cylindrical targets.

29. The plasma spray system of claim 26 wherein the vacuum system comprises a vacuum duct operably adjoined to the vacuum chamber, including:
a blower system coupled to the vacuum duct for generating a vacuum flow;
a chamber outlet having a reversibly constricting chamber outlet end;
a venturi tube section positioned between the vacuum chamber and the blower system; and
a gas detector positioned proximate to the chamber outlet for monitoring the backstreaming of atmospheric gases.

30. The plasma spray system of claim 29 wherein the chamber outlet includes a telescope channel operably coupled to the reversibly constricting chamber outlet end.

31. The plasma spray system of claim 30 wherein the reversibly constricting chamber outlet end includes compression devices operably coupled to rollers that apply pressure to the chamber outlet end thereby constricting the chamber outlet end as the telescope channel is extended into the venturi tube section.

32. The plasma spray system of claim 29 wherein the reversibly constricting chamber outlet includes a tightening clamp extending around the chamber outlet end.

33. The plasma spray system of claim 27 further comprising a central control unit preprogrammed to transmit and control the function of one or more components of the plasma spray system.

34. The plasma spray system of claim 33 wherein the one or more components of the plasma spray system are selected from the group consisting of plasma spray devices, power sources, target assemblies, drive assemblies, coating feeder apparatuses, the vacuum system, water supplies, chamber outlet, telescope channel, tightening clamp, particle control assemblies, preclean gas assemblies and gas assemblies.

35. A vacuum system comprising:
a vacuum duct operably adjoined to the vacuum chamber, including:
a blower system coupled to the vacuum duct for generating a vacuum flow;
a chamber outlet having a reversibly constricting chamber outlet end;
a venturi tube section positioned between the vacuum chamber and the blower system; and
a gas detector positioned proximate to the chamber outlet for monitoring the backstreaming of atmospheric gases.

36. The vacuum system of claim 35 wherein the chamber outlet includes a telescope channel operably coupled to the reversibly constricting chamber outlet end.

37. The vacuum system of claim 36 wherein the reversibly constricting chamber outlet end includes compression devices operably coupled to rollers that apply pressure to the chamber outlet end thereby constricting the chamber outlet end as the telescope channel is extended into the venturi tube section.

38. The vacuum system of claim 35 wherein the reversibly constricting chamber outlet includes a tightening clamp wrapped around the chamber outlet end.

39. A method of uniformly coating a cylindrical target comprising:
a. mounting a cylindrical target to a target assembly;
b. moving the cylindrical target at a constant or variable rate rotationally, laterally, longitudinally or any combination thereof;
c. activating one or more plasma spray devices to generate one or more plasma streams for plasma spraying particles of a coating material toward a deposition zone on the cylindrical target; and
d. plasma spraying particles of coating material on the cylindrical target until a uniform coating of desired thickness is achieved.

40. The method of uniformly coating a cylindrical target of claim 39 further comprising the step of starting and stopping the motion of the cylindrical target at varying points.

41. The method of uniformly coating a cylindrical target of claim 39 further comprising directing gas flow across the plasma streams between the plasma spray devices and the cylindrical target to divert smaller plasma-sprayed particles and other small particles beyond the cylindrical target.

42. The method of uniformly coating a cylindrical target of claim 39 further comprising directing a gas flow or systematic blast onto a surface location of the cylindrical target proximate to the deposition zone before entering the plasma stream to preclean the deposition zone.

43. The method of uniformly coating a cylindrical target of claim 41 further comprising directing a gas flow or systematic blast onto a surface location of the cylindrical target proximate to the deposition zone before entering the plasma stream to preclean the deposition zone.

44. A method of coating a cylindrical target comprising:
a. mounting a cylindrical target to a target assembly;
b. moving the cylindrical target at a constant or variable rate rotationally, laterally, longitudinally or any combination thereof;
c. activating one or more plasma spray devices to generate one or more plasma streams for plasma spraying particles of a coating material toward a deposition zone on the cylindrical target;
d. directing gas flow across the plasma streams between the plasma spray devices and the cylindrical target to divert smaller plasma-sprayed particles and other small particles beyond the cylindrical target; and
e. plasma spraying particles of coating material on the cylindrical target until a uniform coating of predetermined thickness is attained.

45. The method of coating a cylindrical target of claim 44 further comprising the step of starting and stopping the motion of the cylindrical target at varying points.

46. The method of coating a cylindrical target of claim 44 further comprising directing a gas flow or systematic blast of gas onto a surface location of the cylindrical target proximate to the deposition zone before entering the plasma stream to preclean the deposition zone.

47. The method of coating a cylindrical target of claim 44 further comprising maintaining the gas flow at a rate that will divert particles smaller than a predetermined size beyond the deposition zone, while allowing larger particles to deposit on the cylindrical target within the deposition zone.

48. The method of coating a cylindrical target of claim 47 wherein said predetermined size is less than 10 micrometers.

49. The method of coating a cylindrical target of claim 44 wherein the gas flow comprises an anaerobic gas.

50. The method of coating a cylindrical target of claim 49 wherein the anaerobic gas is nitrogen.

51. The method of coating a cylindrical target of claim 44 wherein the gas flow comprises a reducing gas.

52. A method of coating a cylindrical target comprising:
a. mounting a cylindrical target to a target assembly;
b. moving the cylindrical target at a variable or constant rate rotationally, laterally, longitudinally or any combination thereof;
c. starting and stopping the motion of the cylindrical target at varying points;
d. activating one or more plasma spray devices to generate one or more plasma streams for plasma spraying particles of a coating material toward a deposition zone on the cylindrical target;
e. directing a gas flow or systematic blast of gas onto a surface location of the cylindrical target proximate to the deposition zone before entering the plasma streams to preclean the deposition zone; and
f. plasma spraying particles of coating material on the cylindrical target until a uniform coating of predetermined thickness is attained.
